(19) United States
(12) Patent Application Publication
(10) Pub. No.: US 2025/0164891 A1
(43) Pub. Date: May 22, 2025

(54) LAYER STACK FOR EXTREME ULTRAVIOLET LITHOGRAPHY

(71) Applicant: Tokyo Electron Limited, Tokyo (JP)

(72) Inventors: Soo Doo Chae, Albany, NY (US); Jiwoo Kim, Albany, NY (US); Hojin Kim, Albany, NY (US); Choong-man Lee, Nirasaki City (JP); Tek Po Rinus Lee, Albany, NY (US); Ornella Sathoud, Albany, NY (US)

(21) Appl. No.: 18/511,327

(22) Filed: Nov. 16, 2023

(51) Int. Cl. G03F 7/00; G03F 1/46; G03F 1/50; G03F 1/80; G03F 7/004; G03F 7/075

(52) U.S. Cl. CPC G03F 7/70316; G03F 1/46; G03F 1/50; G03F 1/80; G03F 7/0043; G03F 7/075

(57) ABSTRACT

An example lithography stack includes a first layer including an organic material, a second layer disposed over the first layer, where the second layer includes a dielectric material. The lithography stack includes a third layer disposed over the second layer, where the third layer includes a metallic material. The lithography stack includes a fourth layer disposed over the third layer, where the fourth layer includes an extreme ultraviolet (EUV) photoresist.

### TECHNICAL FIELD

The present disclosure relates generally to photoresist for fabricating semiconductor devices and, more particularly, to a layer stack for extreme ultraviolet (EUV) lithography patterning.

### BACKGROUND

Generally, a semiconductor integrated circuit (IC) is fabricated by sequentially depositing a dielectric, conductive, or semiconductor layer over a semiconductor substrate and patterning the layer using photolithography and etch to form electronic and interconnect elements like transistors, resistors, capacitors, metal lines, contacts, and vias in one monolithic structure. At each new technology node, feature sizes are reduced, resulting in increasing the packing density of IC elements to reduce cost.

One direct way to create a higher resolution pattern is to use a shorter wavelength light source. A 248 nm deep ultraviolet (DUV) KrF laser, used to print critical IC patterns at 250 nm and 130 nm nodes, was replaced by a 193 nm ArF laser, starting at a 90 nm node. Features down to 35 nm may be printed using 193 nm lithography with resolution enhancement techniques, such as immersion lithography. The 193 nm optics was further extended to 14 nm and even 10 nm nodes using multiple patterning techniques, which result in higher cost and greater processing complexity associated with additional masks.

At the sub-10 nm regime, DUV may be replaced by the even shorter 13.5 nm wavelength extreme ultraviolet (EUV) technology. While EUV promises high resolution patterning with fewer masks, EUV may still be associated with engineering hurdles to enable various components of photolithography (radiation source, scanner, mask, and resist) to operate in a system having sufficient reliability and throughput of a desired manufacturing system. One factor limiting throughput of EUV patterning is the generally higher exposure dose needed relative to DUV patterning. Further innovations are needed in this area for successful deployment of EUV lithography in high volume semiconductor IC manufacturing.

### SUMMARY

A lithography stack includes a first layer including an organic material, a second layer disposed over the first layer, where the second layer includes a dielectric material. The lithography stack includes a third layer disposed over the second layer, where the third layer includes a metallic material. The lithography stack includes a fourth layer disposed over the third layer, where the fourth layer includes an extreme ultraviolet (EUV) photoresist.

A lithography stack includes a first layer including an organic material, and a second layer overlaid on and in contact with the first layer, where the second layer includes a metallic material. The lithography stack includes a third layer overlaid on and in contact with the second layer, where the third layer includes a dielectric material. The lithography stack includes a fourth layer overlaid on and in contact with the third layer, where the fourth layer includes an extreme ultraviolet (EUV) photoresist.

A method of patterning a structure includes forming a hard mask layer over a substrate stack including a layer to be patterned, and forming a photoresist layer over the hard mask layer. Forming the photoresist layer further includes forming, over the hard mask layer, a first lithography stack layer including an organic material, forming a second lithography stack layer including a dielectric material over the first lithography stack layer, forming a third lithography stack layer including a metallic material over the second lithography stack layer, and forming a fourth lithography stack layer including an extreme ultraviolet (EUV) photoresist over the third lithography stack layer. The method includes patterning the photoresist layer using an EUV lithography process.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is a depiction of a substrate stack in one embodiment;

FIG. 2 is a flowchart describing a lithography process for fabricating a semiconductor device in one embodiment;

FIGS. 3A, 3B, 3C, and 3D are depictions of a substrate stack at various steps in a method for fabricating a semiconductor device in one embodiment;

FIG. 4A is a depiction of a first lithography layer stack for lowered dose EUV exposure;

FIG. 4B is a depiction of a second lithography layer stack for lowered dose EUV exposure;

FIG. 4C is a depiction of a third lithography layer stack for lowered dose EUV exposure;

FIG. 4D is a depiction of a fourth lithography layer stack for lowered dose EUV exposure;

FIG. 5A is an image of a patterned photoresist;

FIG. 5B is a plot of critical dimension versus EUV light dosage;

FIG. 6 is a process of depositing a first lithography layer stack;

FIG. 7 is a process of depositing a second lithography layer stack; and

FIG. 8 is a process of depositing a third lithography layer stack.

### DETAILED DESCRIPTION OF ILLUSTRATIVE EMBODIMENTS

This disclosure describes processes of patterning a substrate using extreme ultraviolet (EUV) lithography in a process flow for fabricating a semiconductor integrated circuit (IC). The example embodiments utilize a lithography layer stack particularly suited for lowered dose extreme ultraviolet (EUV) lithography patterning.

In the following description, details are set forth by way of example to facilitate discussion of the disclosed subject matter. It should be apparent to a person of ordinary skill in the field, however, that the disclosed embodiments are exemplary and not exhaustive of all possible embodiments.

The photolithography process comprises forming a patterned photoresist etch mask by exposing the photoresist to a pattern of actinic radiation. In an EUV lithography process, the actinic radiation may have a wavelength around 13.5 nm. The short wavelength of 13.5 nm EUV may enable printing high resolution patterns without employing multiple patterning techniques that may extend the resolution capability of 193 nm wavelength deep ultraviolet (DUV) and immersion DUV (iDUV) lithography, which use a longer wavelength than EUV. With iDUV and multiple patterning, a number of masks and the associated processing steps may become prohibitively expensive for a process flow for manufacturing ICs at, for example, the 5 nm technology node. Multiple patterning also introduces various errors, e.g., due to poor overlay and alignment, that can pose significant challenges. EUV lithography may enable lithographic patterning using a single patterning step to print, for example, a high-resolution pattern (e.g., a 30 nm pitch line-and-space array) involving one masking level. However, EUV technology may come with certain disadvantages, such as increased costs. A commercial EUV scanner remains several times more expensive as compared to a 193 nm iDUV scanner, despite ongoing development efforts to optimize various components of EUV lithography technology, such as a radiation source, optics, optical mask technology, and an EUV photoresist.

One factor that may offset cost savings associated with EUV's single patterning is a cost of a relatively high EUV exposure dose during EUV lithography. Exposing the photoresist to a higher radiation dose may lengthen exposure time, thereby reducing throughput and increasing manufacturing cost. EUV radiation at 13.5 nm wavelength has a photon energy of 92 eV that is substantially greater than DUV radiation at 193 nm wavelength with a photon energy of 6.4 eV. The greater photon energy of EUV may result in a relatively large dose of EUV radiation to expose the photoresist. For example, a typical dose of 20 mJ/cm² may be used to expose photoresist in a 193 nm iDUV lithography process. With the DUV photon energy of 6.4 eV, the dose of 20 mJ/cm² corresponds to irradiating the photoresist with a photon intensity of about 200 photons/nm². But, at the higher EUV photon energy 92 eV, 20 mJ/cm² is roughly equivalent to a photon intensity of about 14 photons/nm², which may be an insufficient photon intensity to adequately expose the photoresist. Furthermore, a probability that a 92 eV EUV photon penetrates a photoresist film about 200 nm thick is greater than that a corresponding probability for a 6.4 eV DUV photon.

Photons absorbed in a photoresist layer may chemically alter some of the unexposed photoresist molecules to exposed photoresist by photochemical reactions. When the photoresist used in EUV lithography is a positive photoresist, the exposed photoresist is removed when the photoresist is developed. A partially removed photoresist according to the exposed light pattern may result in a patterned photoresist masking layer. An EUV photoresist may also be exposed with energetic electrons that may emerge as a result of interactions of EUV photons with the EUV lithography layer stack.

As will be described in further detail herein, the embodiments described in this disclosure provide examples of an EUV lithography layer stack that may improve the exposure of the EUV photoresist by promoting an increase in energetic electrons for a given EUV photon intensity dose. In particular, as will be described in further detail herein, introduction of a metallic layer in the EUV lithography layer stack may improve the exposure of the EUV photoresist by energetic electrons, which, in turn, may enable a reduction of the EUV radiation dose sufficient to pattern the photoresist layer, which is desirable.

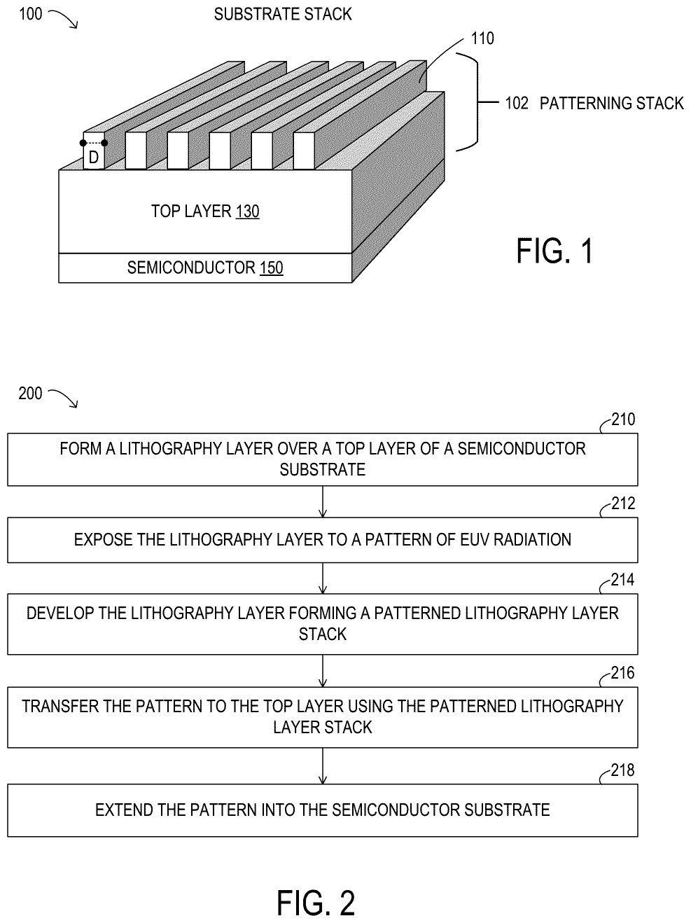

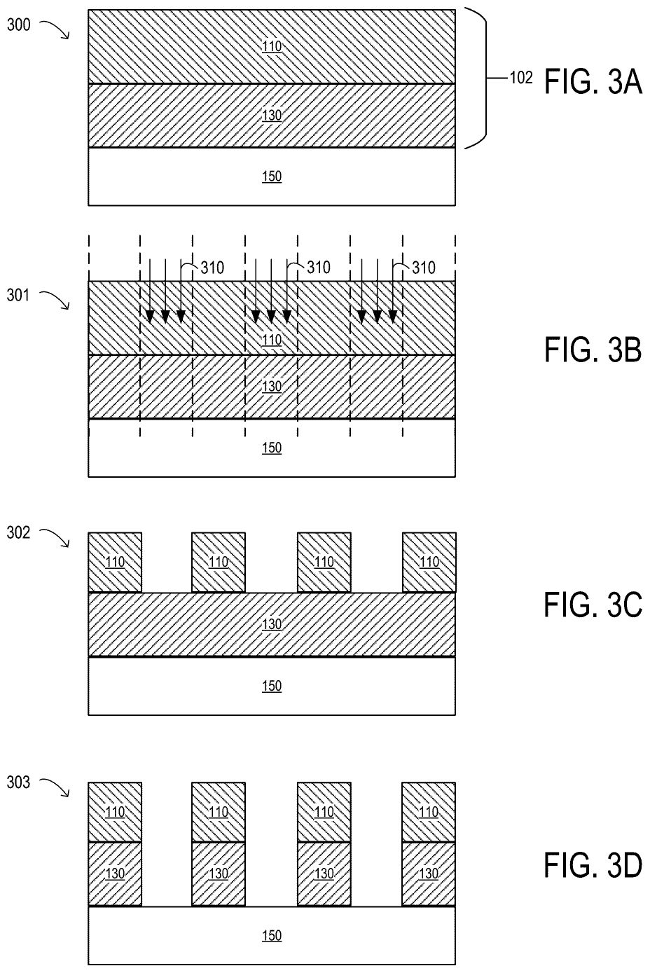

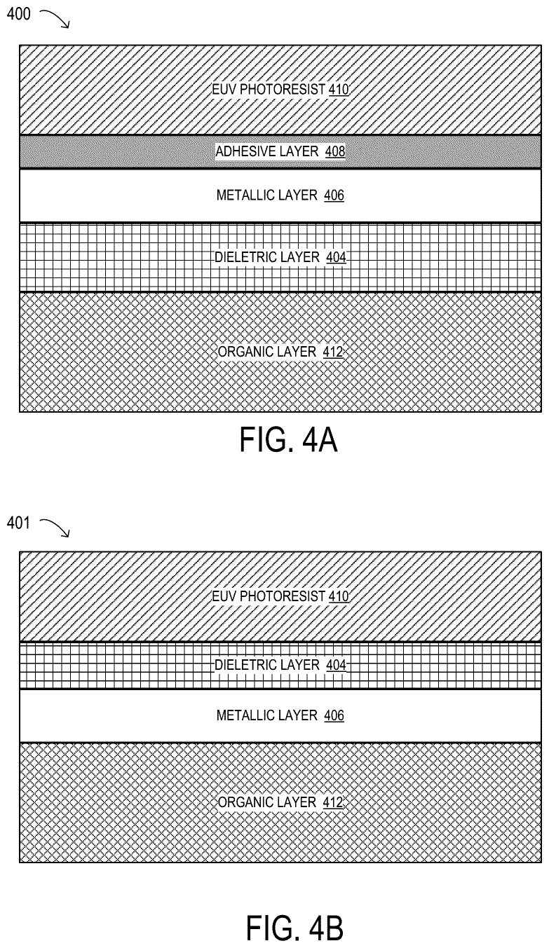

Referring now to the drawings, FIG. 1 shows a perspective view of a semiconductor device in a substrate stack 100. FIG. 1 is a schematic illustration and is not necessarily drawn to scale or perspective. FIG. 1 illustrates substrate stack 100 at an intermediate stage of processing of a EUV lithography process 200, described in further detail below with reference to FIG. 2 and FIGS. 3A-3D. The lithography process associated with substrate stack 100 may be an extreme ultraviolet (EUV) lithography process. An incoming substrate stack 100 having a top layer 130 may be patterned using the lithography process, such as the EUV lithography process 200 (see FIG. 2). The top layer 130 may be, for example, a hard mask layer used as a masking layer at a subsequent etch step. In some embodiments, the hard mask material for the top layer 130 may comprise an inorganic layer such as a silicon layer, silicon nitride, silicon oxide, a metallic layer such as titanium nitride, or an organic layer such as spin-on carbon (SOC), amorphous carbon layer (ACL), or organic dielectric layer (ODL). The top layer 130 may also include organic planarization layer (OPL) over the hard mask layer. In other embodiments, other hard mask layer materials may be used. For example, the hard mask layer material may comprise dielectrics such as silicon nitride, silicon oxide, and metal oxides (e.g., aluminum oxide and hafnium oxide) or metals such as titanium and titanium nitride, or similar.

A two-layer patterning stack 102 comprising top layer 130 and a lithography layer stack 110 is shown in FIG. 1. Lithography layer stack 110 may represent an EUV lithography layer stack for low dose EUV exposure, as described herein. A lithography stack refers to a sacrificial stack of layers formed over the surface of an incoming substrate that participate in the processing used in transferring a pattern of actinic radiation to the layer adjacent below the lithography stack, for example, a semiconductor layer 150 in FIG. 1, which may comprise silicon. As noted, top layer 130 may be a hard mask layer used to etch a target layer below, such as semiconductor layer 150 or another layer below the semiconductor layer 150 (not shown).

In the perspective view illustrated in FIG. 1, lithography layer stack 110 has been exposed and developed to form a dense pattern of parallel lines having a critical dimension D. Lithography layer stack 110 may be selected to be photosensitive to particular wavelengths of UV radiation, such as 13.5 nm EUV light for an EUV lithography layer stack, in various embodiments. The photosensitivity of the pattern of the radiation (e.g., the pattern of dense lines) may be transferred to the lithography layer stack 110. Top layer 130 may be more resistant than lithography layer stack 110 to etchants used in a pattern transfer etch transferring the radiation pattern from lithography layer stack 110 to semiconductor layer 150 of substrate stack 100. Hence, top layer 130 may be utilized as a hard mask in patterning semiconductor layer 150.

Semiconductor layer 150 may collectively represent various other layers associated with an IC, such as various dielectric, metallic, and other semiconductor layers formed over an initial substrate (not shown) that may include a single crystal semiconductor. The initial substrate may comprise bulk silicon, epitaxial silicon over bulk silicon, gallium arsenide, silicon carbide, germanium, silicon on insulator (SOI), or hetero-structures such as gallium nitride on silicon, silicon on sapphire, and the like, and may further include epitaxially grown embedded semiconductor regions such as embedded silicon germanium.

Turning now to FIG. 2, an EUV lithography process 200, or simply process 200, for fabricating a semiconductor device is shown in flowchart format. It is noted that some portions of process 200 may be omitted or rearranged in certain embodiments. EUV lithography process 200 may be used to pattern top layer 130, as also described in cross-sectional views of substrate stack 100 at various intermediate stages of processing, illustrated in FIGS. 3A-3D.

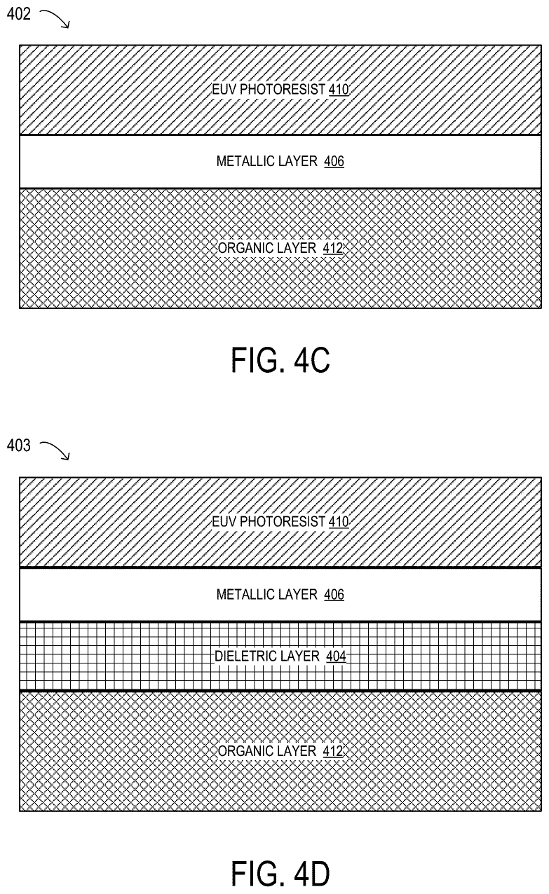

As shown, process 200 may begin at step 210 by forming a lithography layer stack over a top layer of a semiconductor substrate. As noted, the semiconductor substrate may represent various structures, layers, materials used to form a semiconductor device, such as semiconductor layer 150 shown in FIG. 1. At step 212, the lithography layer stack is exposed to a pattern of EUV radiation. The pattern may correspond to a desired structure to be formed by EUV lithography process 200 (see FIG. 3B). The exposure of lithography layer stack 110 at step 212 may be facilitated by a metallic layer in the EUV lithography layer stack represented by lithography layer stack 110 (see also FIGS. 4A and 4B), as described herein, which may enable using a lower dose of EUV radiation in particular embodiments. Specifically, the EUV lithography layer stack represented by lithography layer stack 110 may be enabled to enhance the generation of energetic electrons during exposure to EUV light at step 212 allowing the lower dose of EUV radiation to be effective in sufficiently exposing lithography layer stack 110. At step 214, the lithography layer stack is developed forming a patterned lithography layer stack. Patterned lithography layer stack 110 (see FIG. 1) may represent the pattern resulting from step 214 (see also FIG. 3C). At step 216, the pattern is transferred to the top layer using the patterned lithography layer stack. At step 218, the pattern is extended into the semiconductor substrate.

Referring now to FIGS. 3A, 3B, 3C, and 3D, various cross-sectional depictions show states of substrate stack 100 during EUV lithography process 200 as shown in FIG. 2. FIGS. 3A-3D are schematic illustrations and are not necessarily drawn to scale. In FIG. 3A, an unpatterned stack 300 shows solid layers after deposition of lithography layer stack 110, such as by spin coating.

In FIG. 3B, corresponding to step 212 in FIG. 2, stack 301 is exposed to EUV radiation 310 projected towards stack 301 in a pattern comprising alternating lines of light and darkness. The dashed lines in FIG. 3B delineate the boundaries between light and dark regions. A region where EUV radiation 310 is present is indicated by a group of three parallel arrows pointing downwards and a region that is dark is indicated by an absence of arrows. The result of exposing lithography layer stack 110 with photons of EUV radiation 310 causes photochemical and electrochemical reactions in lithography layer stack 110 that can break covalent bonds, thereby converting the relatively insoluble unexposed positive photoresist polymer to a form that may be dissolved by a chemical developer.

In the example illustrated in FIG. 3B, positive photoresist is used. Accordingly, portions of lithography layer stack 110 in a region irradiated with EUV radiation 310 are subject to a photochemical reaction and are removed during development, while portions of lithography layer stack 110 in dark regions remain unaffected by any photochemical reaction and are not removed during development. As noted, lithography layer stack 110 may be an EUV lithography layer stack having a metallic layer that enables lithography layer stack 110 to sufficiently be exposed with a lower EUV dose, such as by promoting formation of energetic electrons that also expose lithography layer stack 110. As a result, the light and dark pattern of EUV radiation 310 corresponding to the line and space pattern shown in FIG. 1 is produced in lithography layer stack 110, whereby the patterned photoresist lines remaining, as shown in FIG. 1, are located in the dark regions in the pattern of EUV radiation 310.

A result of such a development of lithography layer stack 110 is shown in stack 302 in FIG. 3C, corresponding to FIG. 1. As indicated in step 214 of EUV lithography process 200 in FIG. 2, lithography layer stack 110 is developed using, for example, a chemical solvent that removes exposed photoresist. In addition, any exposed layers of the lithography layer stack 110 such as the metallic layer 406, adhesive layer 408, dielectric layer 404, organic layer 412 (in FIGS. 4A-4B) that are not removed by the developer may be exposed to another chemistry, for example, a wet etch chemistry. In one or more embodiments, the etch for removing the metallic layer 406 may be performed after a bake process. In various embodiments, the development of lithography layer stack 110 may be performed within the coating and developing tool rather than a separate etch chamber. However, in certain embodiments, the metallic layer 406 may be etched in an etch chamber prior to etching the top layer 130.

Patterned lithography layer stack 110 may be a masking layer for transferring the radiation pattern to top layer 130, as indicated in step 216 in FIG. 2.

In FIG. 3D, an etch step extends the pattern formed in stack 302 through the top layer 130 to expose a portion of semiconductor layer 150 of the substrate stack 100 in stack 303. As illustrated in FIG. 3C, the dark regions are protected by photoresist lines of the patterned lithography layer stack 110 that are remaining after patterned top layer 130 has been formed. The combined patterned top layer 130 and the remaining patterned lithography layer stack 110 may form patterning stack 102, as shown in FIGS. 1 and 3A. Patterning stack 102 formed in stack 303 of FIG. 3D may be an etch mask used in a subsequent anisotropic etch step to transfer the radiation pattern to semiconductor layer 150, as indicated in step 218 (not shown in FIG. 3D).

Referring now to FIGS. 4A, 4B, 4C, and 4D cross-sectional layer views of a first lithography layer stack 400, a second lithography layer stack 401, a third lithography layer stack 402, and a fourth lithography layer stack 403 for lowered dose EUV exposure are respectively shown. First through fourth lithography layer stacks 400, 401, 402, and 403 are depicted as schematic illustrations and are not necessarily drawn to scale. First through fourth lithography layer stacks 400, 401, 402, and 403 are examples of the EUV lithography layer stack represented by lithography layer stack 110 in FIGS. 1 and 3A-3D that enables low dose EUV photon intensity, as described herein.

In first lithography layer stack 400 in FIG. 4A, beginning with the lowest layer in order of deposition, an organic layer 412 may be deposited over a structure to be patterned, such as over top layer 130 that has been deposited on a semiconductor layer 150 comprising silicon (see FIG. 1). In reference to organic layer 412, the term “organic” refers generally to the inclusion of carbon that may be present in various forms. In particular embodiments, material forming organic layer 412 may be selected from at least one of the following materials: an organic dielectric material, an amorphous carbon material, and silicon oxycarbide (SiOC).

In first lithography layer stack 400, a dielectric layer 404 is deposited over organic layer 412, such as by covering and being in contact with organic layer 412. In particular embodiments, material forming dielectric layer 404 may be selected from at least one of the following materials: silicon dioxide (SiO₂), silicon nitride (SiN), silicon oxynitride (SiON), silicon oxycarbonitride (SiOCN), aluminum (I) oxide (Al₂O), aluminum (II) oxide (AlO, aluminum monoxide), aluminum (III) oxide (Al₂O₃), an aluminate, titanium (IV) oxide (TiO₂, titanium dioxide), titanium (III) oxide (Ti₂O₃, dititanium trioxide), titanium (II) oxide (TiO, titanium monoxide), trititanium oxide (Ti₃O), dititanium oxide (Ti₂O), a titanium oxide selected from TiₙO₂ₙ₋₁ where 3≤n≤9, hafnium oxide (HfO₂), and tin (IV) oxide (SnO₂).

In first lithography layer stack 400, a metallic layer 406 is deposited over dielectric layer 404, such as by covering and being in contact with dielectric layer 404. The metallic layer 406 may be deposited using a deposition technique such as chemical vapor deposition, plasma enhanced chemical vapor deposition, sputter deposition, physical vapor deposition, and others.

In particular embodiments, material forming metallic layer 406 may be selected from at least one of the following materials: titanium (Ti), tungsten (W), aluminum (Al), indium (In), ruthenium (Ru), tin (Sn), hafnium (Hf), and titanium nitride (TiN). In a particular embodiment, a given thickness of metal is used for metallic layer 406, such as a thickness of 0.5 nm, 1.0 nm, 1.5 nm, 2.0 nm, 2.5 nm, 3.0 nm, 3.5 nm, or 4.0 nm. In other embodiments, different thickness may be used. In certain embodiments, Ti metal, either alone or in alloy form with another metal is used for metallic layer 406. In further embodiments, various other metals or metal alloys may be used for metallic layer 406.

As shown in first lithography layer stack 400, an adhesive layer 408 is deposited over metallic layer 406 and in between metallic layer 406 and an EUV photoresist layer 410. In particular embodiments, adhesive layer 408 may be omitted, while EUV photoresist layer 410 may be deposited directly over and in contact with metallic layer 406 (not shown). As shown, material forming adhesive layer 408 may be selected from at least one of: a bottom anti-reflective material, silicon oxycarbide (SiOC), an organic dielectric material, and an epoxy.

In first lithography layer stack 400, EUV photoresist layer 410 is deposited over adhesive layer 408. In particular embodiments, material forming EUV photoresist layer 410 may be selected from at least one of: an organic photoresist, and a metal oxide photoresist. As noted, in particular embodiments, EUV photoresist layer 410 may be deposited directly over metallic layer 406, such as by covering and being in contact with metallic layer 406.

In second lithography layer stack 401 in FIG. 4B, beginning with the lowest layer in order of deposition, organic layer 412 may be deposited over a structure to be patterned, such as over top layer 130 that has been deposited on a semiconductor layer 150 comprising silicon (see FIG. 1). In second lithography layer stack 401, metallic layer 406 is deposited over organic layer 412, such as by covering and being in contact with organic layer 412. In second lithography layer stack 401, dielectric layer 404 is deposited over metallic layer 406, such as by covering and being in contact with metallic layer 406. In second lithography layer stack 401, EUV photoresist layer 410 is deposited over dielectric layer 404, such as by covering and being in contact with dielectric layer 404.

In third lithography layer stack 402 in FIG. 4C, beginning with the lowest layer in order of deposition, organic layer 412 may be deposited over a structure to be patterned, such as over top layer 130 that has been deposited on a semiconductor layer 150 comprising silicon (see FIG. 1). In third lithography layer stack 402, metallic layer 406 is deposited over organic layer 412, such as by covering and being in contact with organic layer 412. In third lithography layer stack 402, EUV photoresist layer 410 is deposited over metallic layer 406, such as by covering and being in contact with metallic layer 406. The metallic layer 406 may be deposited at a low temperature to avoid decomposition or damage to the organic layer 412. In some embodiments, a first portion of metallic layer 406 may be deposited using a low temperature, such as by atomic layer deposition or chemical vapor deposition. The first portion may then provide protection for underlying organic layer 412, in various embodiments, to enable a second portion of metallic layer 406 to be deposited to a desired total thickness of metallic layer 406 at a higher temperature than used for the first portion, such as by using physical vapor deposition or atomic layer deposition.

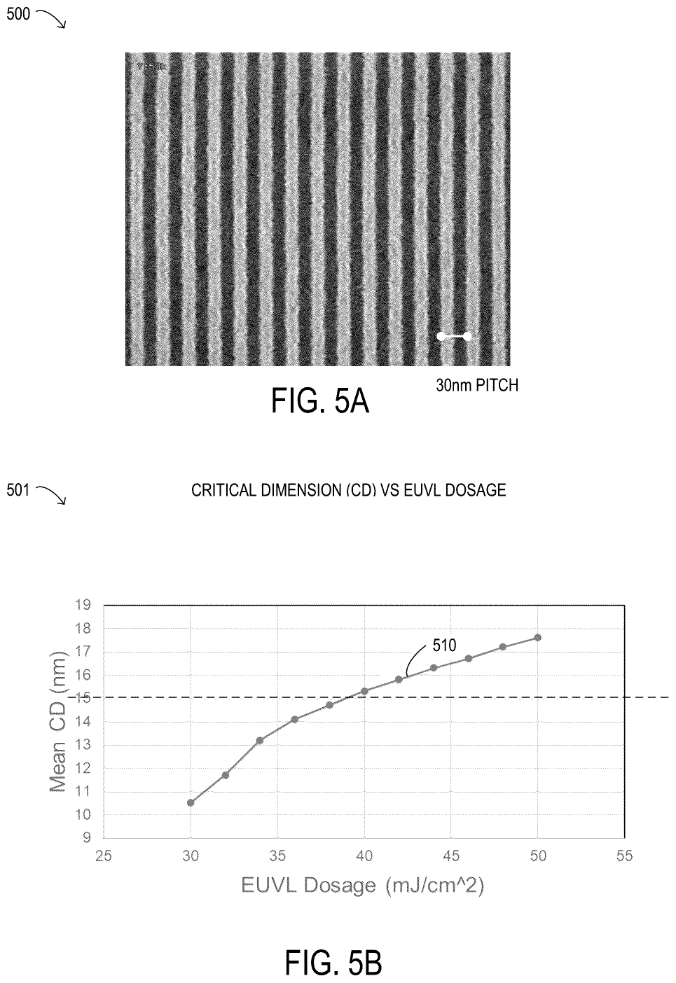

Turning now to FIGS. 5A and 5B, particular embodiments of patterned lithography layer stack 110 for EUV lithography are described in further detail. In FIG. 5A, a top view image 500 of a patterned photoresist having spaced lined features with a pitch dimension of 30 nm is shown, corresponding to dimension D in FIG. 1 of 15 nm representing a single line width. The sample of patterned lithography layer stack 110 shown in image 500 is an EUV lithography layer stack comprising a Ti layer having 4 nm thickness as a metallic layer, and corresponding to fourth lithography layer stack 403 (see FIG. 4D). Furthermore, the clear spatial resolution and low line edge roughness (LER) of the 15 nm wide features evident in image 500 were formed by applying an EUV photon intensity of 40 mJ/cm². A reference sample of patterned photoresist that was identical except for the omission of the 4 nm Ti layer (not shown) was also produced and was subject to at least 70 mJ/cm² EUV photon intensity in order to produce the same 30 nm pitch line features with similarly low LER. The difference to the sample shown in image 500 and the reference sample (not shown) indicates a significant reduction in the EUV photon intensity dose for sufficient photoresist development as a result of including the 4 nm Ti metallic layer in the EUV lithography layer stack.

In FIG. 5B a plot 510 of critical dimension (CD) in nm versus EUV light dosage in mJ/cm² corresponding to EUV photon intensity is shown for the photoresist including the 2 nm thick Ti metallic layer below a metal oxide photoresist, as shown in image 500 in FIG. 5A. Plot 510 shows that the CD of 15 nm was attained with an EUV dosage of about 40 mJ/cm². It is noted that other metals and other thickness may be used in various embodiments, and that plot 510 is a non-limiting example of the advantages of using metallic layer 406 in an EUV lithography layer stack, as also shown in fourth photoresist stack 403 in FIG. 4D, as described herein, to achieve desired EUV lithography performance with lower dose EUV light intensity, which is desirable.

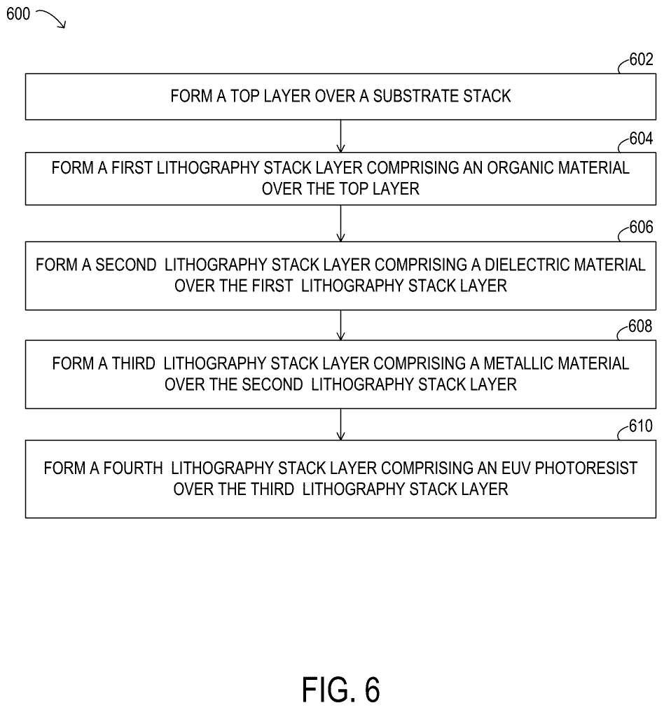

Referring now to FIG. 6, a process 600 of depositing a first lithography layer stack is shown in flowchart format. The first lithography layer stack may be an EUV lithography layer stack that enables low dose EUV photon intensity, such as first lithography layer stack 400 in FIG. 4A and fourth lithography stack 403 in FIG. 4D, as described herein, in particular embodiments. It is noted that some portions of process 600 may be omitted or rearranged in certain embodiments.

Process 600 may begin, at step 602, by forming a top layer over a substrate stack. At step 604, a first lithography stack layer comprising an organic material is formed over the top layer. At step 606, a second lithography stack layer comprising a dielectric material is formed over the first lithography stack layer. At step 608, a third lithography stack layer comprising a metallic material is formed over the second lithography stack layer. At step 610, a fourth lithography stack layer comprising an EUV photoresist is formed over the third lithography stack layer. In some embodiments, adhesive layer 408 may be applied over metallic layer 406 after step 608, but prior to step 610 (see also FIG. 4A).

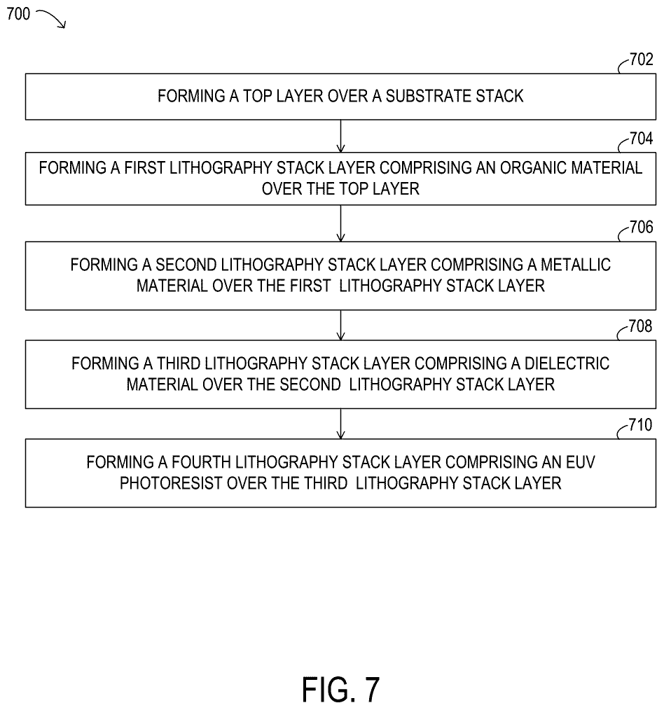

Referring now to FIG. 7, a process 700 of depositing a second lithography layer stack is shown in flowchart format. The second lithography layer stack may be an EUV lithography layer stack that enables low dose EUV photon intensity, such as second lithography layer stack 401 in FIG. 4B, as described herein, in particular embodiments. It is noted that some portions of process 700 may be omitted or rearranged in certain embodiments.

Process 700 may begin, at step 702, by forming a top layer over a substrate stack. At step 704, a first lithography stack layer comprising an organic material is formed over the top layer. At step 706, a second lithography stack layer comprising a metallic material is formed over the first lithography stack layer. At step 708, a third lithography stack layer comprising a dielectric material is formed over the second lithography stack layer. At step 710, a fourth lithography stack layer comprising an EUV photoresist is formed over the third lithography stack layer.

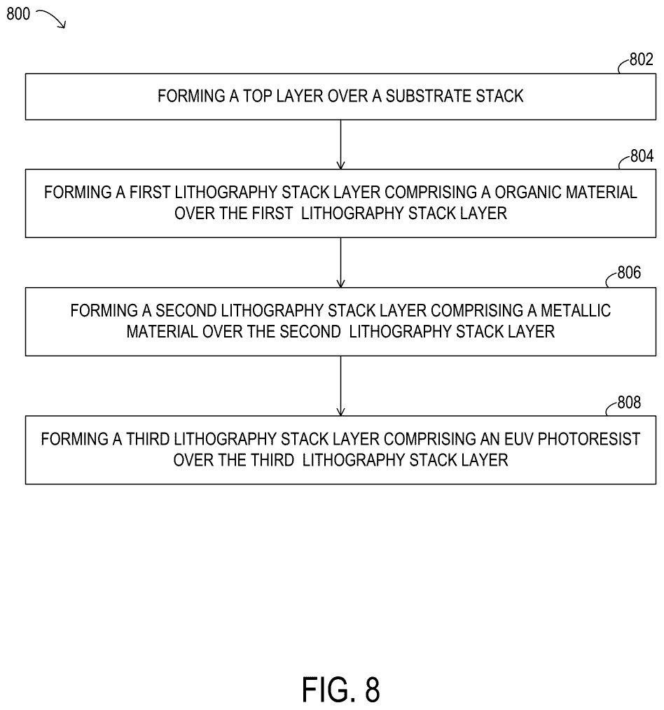

Referring now to FIG. 8, a process 800 of depositing a third lithography layer stack is shown in flowchart format. The third lithography layer stack may be an EUV lithography layer stack that enables low dose EUV photon intensity, such as third lithography layer stack 402 in FIG. 4C, as described herein, in particular embodiments. It is noted that some portions of process 800 may be omitted or rearranged in certain embodiments.

Process 800 may begin, at step 802, by forming a top layer over a substrate stack. At step 804, a first lithography stack layer comprising an organic material is formed over the top layer. At step 806, a second lithography stack layer comprising a metallic material is formed over the first lithography stack layer. At step 808, a third lithography stack layer comprising an EUV photoresist is formed over the second lithography stack layer.

As disclosed herein, an EUV lithography layer stack enables low dose EUV photon intensity to achieve a comparable exposure as other lithography layer stacks with higher dose EUV photon intensity. The EUV lithography layer stack for low dose EUV photon intensity includes a metallic layer.

Example embodiments of the invention are described below. Other embodiments can also be understood from the entirety of the specification as well as the claims filed herein.

Example 1. A lithography stack includes a first layer including an organic material, a second layer disposed over the first layer, where the second layer includes a dielectric material. The lithography stack includes a third layer disposed over the second layer, where the third layer includes a metallic material. The lithography stack includes a fourth layer disposed over the third layer, where the fourth layer includes an extreme ultraviolet (EUV) photoresist.

Example 2. The lithography stack of example 1, where the fourth layer is in contact with the third layer.

Example 3. The lithography stack of one of examples 1 or 2, further including a fifth layer disposed between the third layer and the fourth layer, where the fifth layer includes an adhesive material in contact with the third layer and the fourth layer.

Example 4. The lithography stack of one of examples 1 to 3, where the adhesive material is selected from a group consisting of a bottom anti-reflective material, silicon oxycarbide (SiOC), an organic dielectric material, an epoxy, and combinations thereof.

Example 5. The lithography stack of one of examples 1 to 4, where the organic material is selected from a group consisting of: an organic dielectric material, an amorphous carbon material, silicon oxycarbide (SiOC), and combinations thereof.

Example 6. The lithography stack of one of examples 1 to 5, where the dielectric material is selected from a group consisting of: silicon dioxide (SiO₂), silicon nitride (SiN), silicon oxynitride (SiON), silicon oxycarbonitride (SiOCN), aluminum (I) oxide (Al2O), aluminum (II) oxide (AlO, aluminum monoxide), aluminum (III) oxide (Al₂O₃), an aluminate, titanium (IV) oxide (TiO₂, titanium dioxide), titanium (III) oxide (Ti₂₀₃, dititanium trioxide), titanium (II) oxide (TiO, titanium monoxide), trititanium oxide (Ti₃₀), dititanium oxide (Ti₂₀), a titanium oxide selected from TiₙO₂ₙ₋₁ where 3≤n≤9, hafnium oxide (HfO₂), and tin (IV) oxide (SnO₂), and combinations thereof.

Example 7. The lithography stack of one of examples 1 to 6, where the metallic material is selected from a group consisting of: titanium (Ti), tungsten (W), aluminum (Al), indium (In), ruthenium (Ru), tin (Sn), hafnium (Hf), titanium nitride (TiN), and combinations thereof.

Example 8. The lithography stack of one of examples 1 to 7, where the EUV photoresist is selected from a group consisting of: an organic photoresist, and a metal oxide photoresist.

Example 9. A lithography stack includes a first layer including an organic material, and a second layer overlaid on and in contact with the first layer, where the second layer includes a metallic material. The lithography stack includes a third layer overlaid on and in contact with the second layer, where the third layer includes a dielectric material. The lithography stack includes a fourth layer overlaid on and in contact with the third layer, where the fourth layer includes an extreme ultraviolet (EUV) photoresist.

Example 11. The lithography stack of one of examples 9 or 10, where the metallic material is selected from a group consisting of titanium (Ti), tungsten (W), aluminum (Al), indium (In), ruthenium (Ru), tin (Sn), hafnium (Hf), titanium nitride (TiN), and combinations thereof.

Example 12. The lithography stack of one of examples 9 to 11, where the EUV photoresist is selected from a group consisting of an organic photoresist, a metal oxide photoresist, and combinations thereof.

Example 13. A method of patterning a structure includes forming a hard mask layer over a substrate stack including a layer to be patterned, and forming a photoresist layer over the hard mask layer. Forming the photoresist layer further includes forming, over the hard mask layer, a first lithography stack layer including an organic material, forming a second lithography stack layer including a dielectric material over the first lithography stack layer, forming a third lithography stack layer including a metallic material over the second lithography stack layer, and forming a fourth lithography stack layer including an extreme ultraviolet (EUV) photoresist over the third lithography stack layer. The method includes patterning the photoresist layer using an EUV lithography process.

Example 14. The method of example 13, where forming the fourth lithography stack layer further includes forming the fourth lithography stack layer in contact with the third lithography stack layer.

Example 15. The method of one of examples 13 or 14, further including: forming a fifth photoresist layer between the third lithography stack layer and the fourth lithography stack layer, where the fifth photoresist layer includes an adhesive material in contact with the third lithography stack layer and the fourth lithography stack layer.

Example 16. The method of one of examples 13 to 15, where the adhesive material is selected from a group consisting of: a back-scattering anti-reflective material, silicon oxycarbide (SiOC), an organic dielectric material, an epoxy, and combinations thereof.

Example 17. The method of one of examples 13 to 16, where the organic material includes an organic dielectric material, an amorphous carbon material, or silicon oxycarbide (SiOC).

Example 18. The method of one of examples 13 to 17, where the dielectric material is selected from a group consisting of silicon dioxide (SiO₂), silicon nitride (SiN), silicon oxynitride (SiON), silicon oxycarbonitride (SiOCN), aluminum (I) oxide (Al2O), aluminum (II) oxide (AlO, aluminum monoxide), aluminum (III) oxide (Al2O3), an aluminate, titanium (IV) oxide (TiO2, titanium dioxide), titanium (III) oxide (Ti2O3, dititanium trioxide), titanium (II) oxide (TiO, titanium monoxide), trititanium oxide (Ti3O), dititanium oxide (Ti2O), a titanium oxide selected from TinO2n-1 where 3≤n≤9, hafnium oxide (HfO2), and tin (IV) oxide (SnO2), and combinations thereof.

Example 19. The method of one of examples 13 to 18, where the metallic material includes titanium (Ti), tungsten (W), aluminum (Al), indium (In), ruthenium (Ru), or tin (Sn).

Example 20. The method of one of examples 13 to 19, where the EUV photoresist includes an organic photoresist or a metal oxide photoresist.

Example 21. The method of one of examples 13 to 20, where patterning the photoresist layer includes: exposing the photoresist layer to an extreme ultraviolet radiation through an optical mask; developing the fourth lithography stack layer to form patterns in the fourth lithography stack layer; forming patterns in the photoresist layer using the patterns in the fourth lithography stack layer as an etch mask; and patterning the hard mask layer with the patterns in the photoresist layer; and patterning the layer to be patterned with the patterned hard mask as an etch mask.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A lithography stack comprising:
a first layer comprising an organic material;
a second layer disposed over the first layer, the second layer comprising a dielectric material;
a third layer disposed over the second layer, the third layer comprising a metallic material; and
a fourth layer disposed over the third layer, the fourth layer comprising an extreme ultraviolet (EUV) photoresist.

2. The lithography stack of claim 1, wherein the fourth layer is in contact with the third layer.

3. The lithography stack of claim 1, further comprising a fifth layer disposed between the third layer and the fourth layer, wherein the fifth layer comprises an adhesive material in contact with the third layer and the fourth layer.

4. The lithography stack of claim 3, wherein the adhesive material is selected from a group consisting of a bottom anti-reflective material, silicon oxycarbide (SiOC), an organic dielectric material, an epoxy, and combinations thereof.

5. The lithography stack of claim 1, wherein the organic material is selected from a group consisting of: an organic dielectric material, an amorphous carbon material, silicon oxycarbide (SiOC), and combinations thereof.

6. The lithography stack of claim 1, wherein the dielectric material is selected from a group consisting of: silicon dioxide (SiO2), silicon nitride (SiN), silicon oxynitride (SiON), silicon oxycarbonitride (SiOCN), aluminum (I) oxide (Al₂O), aluminum (II) oxide (AlO, aluminum monoxide), aluminum (III) oxide (Al2O₃), an aluminate, titanium (IV) oxide (TiO2, titanium dioxide), titanium (III) oxide (Ti2O3, dititanium trioxide), titanium (II) oxide (TiO, titanium monoxide), trititanium oxide (Ti3O), dititanium oxide (Ti2O), a titanium oxide selected from TinO2n-1 where 3≤n≤9, hafnium oxide (HfO2), and tin (IV) oxide (SnO2), and combinations thereof.

7. The lithography stack of claim 1, wherein the metallic material is selected from a group consisting of: titanium (Ti), tungsten (W), aluminum (Al), indium (In), ruthenium (Ru), tin (Sn), hafnium (Hf), titanium nitride (TiN), and combinations thereof.

8. The lithography stack of claim 1, wherein the EUV photoresist is selected from a group consisting of an organic photoresist, a metal oxide photoresist, and combinations thereof.

9. A lithography stack comprising:
a first layer comprising an organic material;
a second layer overlaid on and in contact with the first layer, the second layer comprising a metallic material;
a third layer overlaid on and in contact with the second layer, the third layer comprising a dielectric material; and
a fourth layer overlaid on and in contact with the third layer, the fourth layer comprising an extreme ultraviolet (EUV) photoresist.

10. The lithography stack of claim 9, wherein the dielectric material is selected from a group consisting of silicon dioxide (SiO2), silicon nitride (SiN), silicon oxynitride (SiON), silicon oxycarbonitride (SiOCN), aluminum (I) oxide (Al₂O), aluminum (II) oxide (AlO, aluminum monoxide), aluminum (III) oxide (Al2O3), an aluminate, titanium (IV) oxide (TiO2, titanium dioxide), titanium (III) oxide (Ti2O3, dititanium trioxide), titanium (II) oxide (TiO, titanium monoxide), trititanium oxide (Ti3O), dititanium oxide (Ti2O), a titanium oxide selected from TinO2n-1 where 3≤n≤9, hafnium oxide (HfO2), and tin (IV) oxide (SnO2), and combinations thereof.

11. The lithography stack of claim 9, wherein the metallic material is selected from a group consisting of titanium (Ti), tungsten (W), aluminum (Al), indium (In), ruthenium (Ru), tin (Sn), hafnium (Hf), titanium nitride (TiN), and combinations thereof.

12. The lithography stack of claim 9, wherein the EUV photoresist is selected from a group consisting of an organic photoresist, a metal oxide photoresist, and combinations thereof.

13. A method of patterning a structure, the method comprising:
forming a hard mask layer over a substrate stack comprising a layer to be patterned;
forming a photoresist layer over the hard mask layer, the forming of the photoresist layer further comprising
forming, over the hard mask layer, a first lithography stack layer comprising an organic material,
forming a second lithography stack layer comprising a dielectric material over the first lithography stack layer,
forming a third lithography stack layer comprising a metallic material over the second lithography stack layer, and
forming a fourth lithography stack layer comprising an extreme ultraviolet (EUV) photoresist over the third lithography stack layer; and
patterning the photoresist layer using an EUV lithography process.

14. The method of claim 13, wherein forming the fourth lithography stack layer further comprises forming the fourth lithography stack layer in contact with the third lithography stack layer.

15. The method of claim 13, further comprising:
forming a fifth photoresist layer between the third lithography stack layer and the fourth lithography stack layer, wherein the fifth photoresist layer comprises an adhesive material in contact with the third lithography stack layer and the fourth lithography stack layer.

16. The method of claim 15, wherein the adhesive material is selected from a group consisting of: a back-scattering anti-reflective material, silicon oxycarbide (SiOC), an organic dielectric material, an epoxy, and combinations thereof.

17. The method of claim 13, wherein the organic material comprises an organic dielectric material, an amorphous carbon material, or silicon oxycarbide (SiOC).

18. The method of claim 13, wherein the dielectric material is selected from a group consisting of silicon dioxide (SiO2), silicon nitride (SiN), silicon oxynitride (SiON), silicon oxycarbonitride (SiOCN), aluminum (I) oxide (Al2O), aluminum (II) oxide (AlO, aluminum monoxide), aluminum (III) oxide (Al2O3), an aluminate, titanium (IV) oxide (TiO2, titanium dioxide), titanium (III) oxide (Ti2O3, dititanium trioxide), titanium (II) oxide (TiO, titanium monoxide), trititanium oxide (Ti3O), dititanium oxide (Ti2O), a titanium oxide selected from TinO2n-1 where 3≤n≤9, hafnium oxide (HfO2), and tin (IV) oxide (SnO2), and combinations thereof.

19. The method of claim 13, wherein the metallic material comprises titanium (Ti), tungsten (W), aluminum (Al), indium (In), ruthenium (Ru), or tin (Sn).

20. The method of claim 13, wherein the EUV photoresist comprises an organic photoresist or a metal oxide photoresist.

21. The method of claim 13,
wherein patterning the photoresist layer comprises:
exposing the photoresist layer to an extreme ultraviolet radiation through an optical mask;
developing the fourth lithography stack layer to form patterns in the fourth lithography stack layer;
forming patterns in the photoresist layer using the patterns in the fourth lithography stack layer as an etch mask; and
patterning the hard mask layer with the patterns in the photoresist layer; and
patterning the layer to be patterned with the patterned hard mask as an etch mask.
